(19) United States
(12) Patent Application Publication
(10) Pub. No.: US 2026/0182271 A1
(43) Pub. Date: Jun. 25, 2026

(54) IMPLANTATION WHEEL FOR FORMING A PLANE OF WEAKNESS IN A PLURALITY OF DONOR WAFERS

(71) Applicant: Soitec, BERNIN (FR)

(72) Inventors: Nadia Ben Mohamed, BERNIN (FR); Olivier Petit, BERNIN (FR); Franck Colas, BERNIN (FR); Damien Radisson, BERNIN (FR); Francois Rieutord, BERNIN (FR)

(21) Appl. No.: 18/864,764

(22) PCT Filed: May 10, 2023
(86) PCT No.: PCT/EP2023/062394

§ 371 Date: Nov. 11, 2024

(30) Foreign Application Priority Data
May 11, 2022 (FR) FR2204475

(51) Int. Cl. H10P 30/20; H01J 37/20; H01J 37/317; H10P 90/00

(52) U.S. Cl. CPC H10P 30/208; H01J 37/20; H01J 37/3171; H10P 30/204; H10P 90/1916

(57) ABSTRACT

An implantation wheel for forming a plane of weakness in a plurality of donor wafers comprises a main disk and a plurality of wafer supports arranged on one face of the main disk. Each wafer support has a host surface on which a so-called “rear” face of a donor wafer is placed. According to a first aspect, the host surface at least partially comprises a superficial elastomer layer, the superficial elastomer layer having a dimension at least equal to that of the rear face of the donor wafer. According to another aspect, each host surface of the plurality of wafer supports has a convex shape, the convex shape being chosen to correspond to the shape of the donor wafer as the donor wafer deforms under the effect of temperature.

### CROSS-REFERENCE TO RELATED APPLICATIONS

This application is a national phase entry under 35 U.S.C. § 371 of International Patent Application PCT/EP2023/062394, filed May 10, 2023, designating the United States of America and published as International Patent Publication WO 2023/217845 A1 on Nov. 16, 2023, which claims the benefit under Article 8 of the Patent Cooperation Treaty of French Patent Application Serial No. FR2204475, filed May 11, 2022.

### TECHNICAL FIELD

The present disclosure falls within the field of ion implantation, and relates more particularly to ion implantation equipment suitable for forming a plane of weakness in a plurality of donor wafers as part of a thin-layer transfer method implemented using SMART CUT® technology.

### BACKGROUND

US 2020/0186117 A1 proposes to transfer a thin layer of a ferroelectric material onto a substrate using SMART CUT® technology. The substrate has a different coefficient of thermal expansion to that of the ferroelectric material making up the thin layer. It may, in particular, be a silicon substrate.

SMART CUT® technology defines the thin layer by introducing light atomic species into a donor substrate, with the light species concentrating in a plane of weakness located at the average penetration depth of the species. The donor substrate is then joined to the support, and the layer is transferred by detaching the thin layer at the plane of weakness. In the case of a layer made of a ferroelectric and/or piezoelectric material, and when the light atomic species are chosen from among hydrogen ions and helium ions, this detachment is caused by a modest rise in the temperature to which the assembly is subjected, on the order of 170° C.

To limit the stresses that develop in the assembly when the temperature is raised, particularly during the detachment stage just mentioned, document US 2020/0186117 A1 proposes to form the donor substrate of the assembly from a thick layer formed from the ferroelectric material and a handling substrate, the coefficient of thermal expansion of the handling substrate being similar to that of the support substrate. Such a donor substrate is referred to as a donor heterostructure in the remainder of this disclosure.

The step of introducing light atomic species into the donor heterostructure can be carried out using ion implantation equipment. FIGS. 1A and 1B show a schematic view of a known configuration of such equipment.

A wheel 1 of an ion implantation device comprises a disk 1a arranged in a plane at a slight angle to the vertical (typically between 5° and) 10°. On one of its sides, the wheel carries a plurality of supports 2 for respectively receiving a plurality of donor heterostructures. The disk is rotated around a perpendicular axis R passing through its center, at speeds of up to 1,200 rpm. The supports have wedges 2a against which the edges of the donor heterostructures bear when the wheel is rotated at high speed. During this rotation, the exposed faces of the donor heterostructures are successively placed opposite a source S of ions of light atomic species (e.g., hydrogen or helium ions) accelerated to a given energy and shaped into an ion beam F defining an implantation current. For a given implanted species, the implantation energy, implantation current and duration of exposure to the beam form the implantation conditions. The energy defines the average penetration depth of the ions, and the current defines the implanted dose for a given exposure time. The beam F scans all exposed surfaces of the donor heterostructures.

Such ion implantation equipment is known, for example, from US 2007/0158583 A1, U.S. Pat. No. 4,832,781 or U.S. Pat. No. 5,040,484.

The power generated by ions entering a donor heterostructure tends to heat up the heterostructure. To prevent overheating, the main disk and wheel supports are fitted with ducts through which a cooling fluid, typically water, circulates. The substrates against which the donor heterostructures are clamped act as heat sinks, so it's important that the heterostructures are in intimate contact with their substrate to promote heat dissipation. These supports (which can be made of a block of aluminum to help dissipate the heat) are generally fitted with a superficial elastomer portion to ensure intimate contact.

The aim is generally to reduce the duration of the implantation step by increasing the beam current, which tends to increase the power supplied to the donor heterostructures and hence their temperature.

When seeking to increase the implantation current of a donor heterostructure featuring a thick ferroelectric layer, exfoliation of the thin layer was observed during the implantation step itself. This undesirable phenomenon, which renders the layer transfer step impossible, has occurred despite all the care taken to cool the implantation disk supports during this step.

### BRIEF SUMMARY

One aim of the present disclosure is to propose an implantation wheel to remedy this problem. More particularly, one aim of the present disclosure is to offer an implantation wheel particularly suited to implanting a donor heterostructure over a wide range of implantation conditions and without causing premature exfoliation of the donor heterostructure.

In order to achieve this aim, the object of the present disclosure proposes an implantation wheel for forming a plane of weakness in a plurality of donor wafers, the wheel comprising a main disk and a plurality of wafer supports arranged on one face of the main disk, the wheel comprising a cooling circuit for cooling the wafer supports and/or the main disk, each wafer support having a host surface on which a so-called “rear” face of a donor wafer is placed.

According to the present disclosure, each host surface of the plurality of wafer supports has a convex shape, the convex shape being chosen to correspond to the shape of the donor wafer as the latter deforms under the effect of temperature.

According to other advantageous non-limiting features of this aspect of the present disclosure, taken alone or according to any technically feasible combination:
each host surface comprises a superficial elastomer layer on which the rear face of a donor wafer rests, the superficial elastomer layer having a dimension at least equal to that of the rear face of the donor wafer so as to enable the entire extent of the rear face of the donor wafer to be brought into contact with the wafer support;
the superficial elastomer layer has a variable thickness, this variable thickness defining the convex shape of the wafer support;
the convex shape can be either a concave recess or a convex dome;
the concave recess or convex dome has a height of between 0.1 mm and 5 mm;
the implantation wheel has an axis of symmetry defining an axis of rotation and each host surface of the plurality of wafer supports is oriented toward the axis of rotation so that a component normal to the host surface of the centrifugal force applies to the donor wafer during rotation of the wheel and presses it against the host surface;
each wafer support is provided with a wedge for retaining a donor wafer by opposing a component coplanar with the host surface of the centrifugal force applied to the donor wafer during the rotation of the wheel;
the highest elevation of the host surface of each wafer support is at the wedge;
each wafer support is fitted with a retractable pin;
each wafer support is fitted with at least one clip for positioning and retaining a wafer against the wedge; and
the host surface of each wafer support has an elevation, the elevation of the host surface relative to the base of the support, that is highest at the wedge.

### BRIEF DESCRIPTION OF THE DRAWINGS

Other features and advantages of the present disclosure will emerge from the following detailed description of example embodiments of the present disclosure with reference to the appended figures, wherein:

FIG. 1A shows a schematic view of a configuration of ion implantation equipment of the prior art and in accordance with the present disclosure;

FIG. 1B shows a schematic front view of an implantation wheel according to the prior art and in accordance with the present disclosure;

FIGS. 2A and 2B show a donor wafer arranged on a wafer support of the prior art before and during an ion implantation step, respectively; and

FIGS. 3A-3E show the wafer supports of an implantation wheel according to the present disclosure.

### DETAILED DESCRIPTION

The expression “thermal expansion coefficient” used in the remainder of this disclosure in relation to a layer or substrate refers to the expansion coefficient in a direction defined in the main plane defining this layer or substrate. If the material is anisotropic, the retained value of the coefficient will be the value with the greatest amplitude. The value of the coefficient is that which is measured at room temperature.

### Preparatory Experiments

To understand the origin of the exfoliation phenomenon described in the introduction to this disclosure, a series of exploratory experiments has been carried out. In these experiments, the spatial temperature profile of a donor heterostructure was measured as it developed in this heterostructure during an implantation step under conditions designed to form a plane of weakness using SMART CUT® technology. Specifically, prior art ion implantation equipment was used to introduce a hydrogen dose of 3.0×10¹⁶ at/cm² at an implantation current of 16 mA and an energy of around 137 keV. The donor heterostructure consisted of a layer of piezoelectric material, 15-20 microns thick, bonded to a silicon wafer. The temperature of the heterostructure was measured by distributing on its front face, that is, the face exposed to the ion beam, a plurality of heat-sensitive adhesive patches covered with a KAPTON® film. Each patch has a visual indicator of the maximum temperature to which it has been exposed. By arranging these patches on one side of the wafer, and recording the visual indicators of each patch at the end of the experiment, it can be estimated the spatial temperature profile that has developed in the wafer during the implantation step.

The same experiment was reproduced, under the same implantation conditions, this time applying the implantation step to a solid silicon wafer, identical to the wafer forming the handling substrate of the donor heterostructure. The table below shows the results of these experiments.

| | Edge temperature | | Center temperature | |
|---|---|---|---|---|
| Silicon wafer | 54-64° | C. | 46-49° | C. |
| Hetero-structure | 132-166° | C. | >166° | C. |

The results of these experiments show that the temperature at which a donor heterostructure is raised is surprisingly much higher than that at which a simple silicon wafer is raised. It should be noted that this temperature, which can reach and even exceed 160° C., approaches, or even reaches, the exfoliation temperature, which is close to the temperature that causes the detachment of a ferroelectric thin layer in the application of SMART CUT® technology, as mentioned in the introduction. It is therefore easy to see why exfoliation of the thin layer can be observed during the implantation step itself.

Moreover, the spatial temperature profile is reversed when implanting a silicon wafer (with the center rising at a lower temperature than the edge) compared to when implanting a donor heterostructure (with the edge rising at a lower temperature than the center).

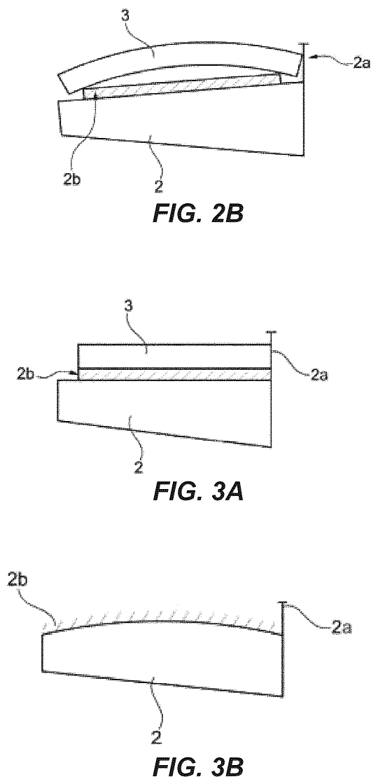

In seeking to interpret these results, it was observed that in the prior art implantation equipment used to carry out these experiments, the superficial elastomer portion of the implantation wheel supports, which ensures thermal contact between a support and the implanted wafer, did not extend entirely under the whole rear face of that wafer. As can be seen in FIG. 2A, which shows a donor heterostructure 3 arranged on a wafer support prior to the start of the implantation step, this circular superficial elastomer portion 2b, on which an equally circular wafer 3 is centered, has a smaller diameter than that of the wafer. A peripheral ring C on the rear face of the wafer (a few millimeters wide) is therefore not in intimate contact with this superficial elastomer layer 2b, and the heat that accumulates there during the implantation step cannot escape. This heat therefore tends to diffuse toward a central portion of the wafer 3, raising its average temperature. In the case of a donor heterostructure 3 formed, as mentioned in the introduction, by a thick layer of ferroelectric material and a handling substrate, with different coefficients of expansion, the rise in average temperature tends to deform the donor heterostructure 3, which takes on a convex shape to accommodate these stresses. This situation is shown in FIG. 2B, which shows the donor heterostructure 3 deformed by its temperature rise during the implantation step. This convex shape tends to move the central part of the heterostructure away from the implantation wheel support, and preserves contact on a peripheral circle only, as is clearly visible in FIG. 2B. The stresses generated by the difference in coefficients of expansion are greater than the centrifugal force that tends to keep the heterostructure in intimate contact with the superficial elastomer portion of the support. With this intimate contact lost, the heat that accumulates in the donor heterostructure 3 during implantation can no longer be evacuated with the same efficiency, which tends to amplify the phenomenon of deformation of the heterostructure and, through a thermal runaway effect, causes its temperature to rise until it reaches at least the exfoliation temperature locally. This also explains why the central part of the donor heterostructure 3, which is no longer in contact with the substrate 2, tends to reach a higher temperature than the edge, which remains in contact with the substrate 2.

### Improved Implantation Wheel

This section of the disclosure proposes an improved implantation wheel to prevent the excessive temperature rise of a donor wafer, and, in particular, a donor heterostructure, when exposed to a beam of light species ions (typically hydrogen or helium) to form a plane of weakness therein.

This wheel is particularly useful when the donor wafer is a donor heterostructure, having a thick layer arranged on a handling substrate, the coefficients of thermal expansion of the handling substrate and the thick layer being different from each other, for example, by at least 5%. However, the wheel can be used for any type of donor wafer.

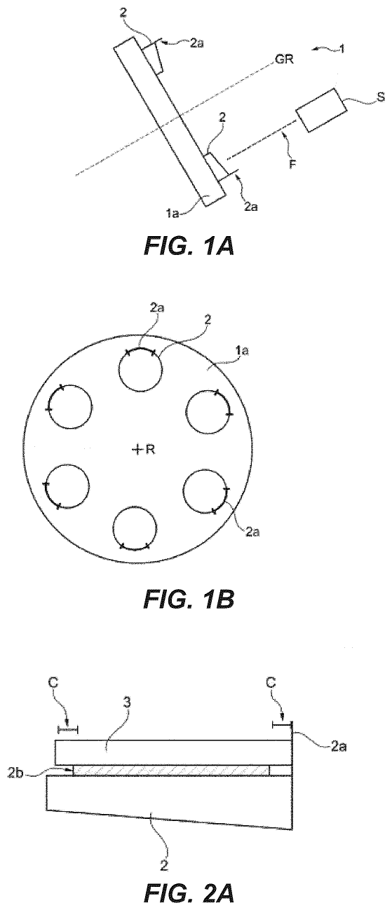

Similar to what has been explained in relation to the description of FIGS. 1A and 1B, the wheel comprises a main disk 1a and a plurality of wafer supports 2 arranged, for example, annularly, on one side of the main disk 1a. Each wafer support 2 has a host surface designed to receive a “rear” face of a donor wafer. The wafer support 2 comprises a solid metal part, for example, aluminum, which defines the host surface. This host surface is advantageously provided, at least partially, with a superficial elastomer layer. This layer can be roughened to limit slippage of the donor wafer, maintain intimate contact with the rear of the wafer, and enable efficient evacuation of any heat that may build up during the ion implantation step. The material constituting this layer is therefore chosen to be a good thermal conductor, in order to allow heat to flow toward the wafer support. This material can be loaded with thermally conductive particles, such as carbon or alumina, to enhance the thermal conductivity of the layer. The superficial elastomer layer can be deposited on the metal part of the wafer support, for example, using a spin-coating process. Alternatively, the layer can be prepared as an adhesive film, cut to the dimensions of the metal part of the wafer support 2 and placed on the host surface.

The support 2 and/or the main disk 1a can be cooled by a cooling circuit, in order to evacuate heat from the donor wafers throughout the implantation step.

The wheel 1 has an axis of symmetry R (perpendicular to the faces of the main disk making up the wheel and passing through its center) that defines the wheel's axis of rotation. During an implantation step, the wheel 1 is rotated around this axis R (completed by a scanning movement), in order to successively expose the donor wafers held on their support to the light ion beam produced by the source of the implantation equipment.

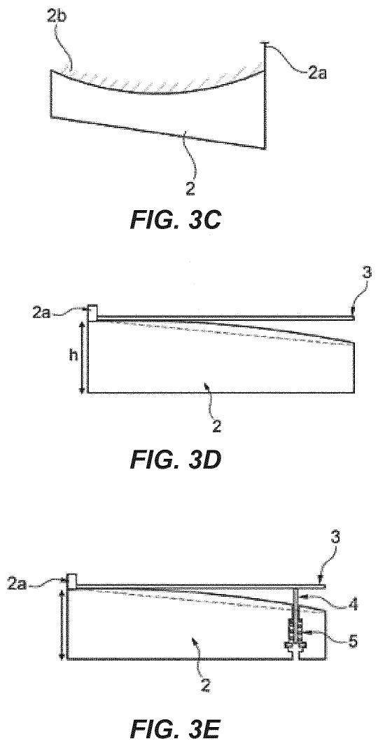

Each host surface of the plurality of wafer supports 2 is oriented toward the axis of rotation so that a component normal to the host surface of the centrifugal force is applied to the donor wafer as the wheel 1 rotates. This force tends to press the donor wafer against the host surface. In order to orient the bearing surface of a support toward the axis of rotation of the wheel on which it rests, the support is thinner on the side facing the center of the wheel than on the side facing away from the center of the wheel, as can be clearly seen in FIG. 3A.

Each wafer support 2 is fitted with a shim 2a, typically a lateral shim that matches the shape of a donor wafer, enabling this wafer to be retained by opposing a component coplanar with the host surface of the centrifugal force applied to the wafer as the wheel rotates.

Finally, as is well known, each wafer support is fitted with at least one clip (not shown) to precisely position a donor wafer on its support and hold this wafer against the wedge when the wheel is not turning.

According to a first embodiment shown in FIG. 3A, the elastomer layer 2b has a dimension at least equal to that of the rear face of the donor wafer 3, so as to enable the entire extent of this rear face to be brought into contact with the wafer support 2. Advantageously, the elastomer layer 2b has a dimension strictly greater than that of the rear face of the donor wafer 3.

In this way, excess heat is prevented from building up during the implantation step, in a peripheral ring C of the wafer, which is therefore not in intimate contact with the elastomer layer 2b, as is the case in the prior art configuration. This prevents or delays the onset of the runaway phenomenon that, through a gradual rise in the average temperature of the donor wafer 3, leads to deformation of the wafer and loss of intimate contact between its rear face and the elastomer layer. It is therefore possible to carry out this implantation step without raising the average temperature of this plate above the critical temperature that causes exfoliation of at least part of the thin layer. As a corollary, it is therefore possible to apply implantation conditions (defined mainly, as a reminder, by implantation current, implantation energy and ion beam exposure time) over a wider range than is possible with prior-art equipment. In particular, the beam exposure time, and therefore the duration of this implantation step, can be reduced by increasing the implantation current, without risking the exfoliation phenomenon.

According to a second embodiment, examples of which can be found in FIGS. 3B and 3C, each host surface of the plurality of donor wafer supports 2 has a convex shape, the convex shape being chosen to correspond to the shape, convex or concave, of the wafer when the latter deforms under the effect of temperature.

This convex shape of the support 2, which tends to match the shape of the donor wafer as the latter rises in temperature during the implantation step, preserves intimate contact between the rear face of this wafer and the support's host surface, ensures that heat is dissipated by diffusion into the support 2, and thus limits the rise in temperature during the implantation step.

It should be noted that when the donor wafer, which is flat and undeformed at room temperature, is initially placed on such a convex support, intimate contact is not achieved over the entire length of the wafer. But the normal component of the centrifugal force, which is applied as soon as the wheel is rotated, tends to press the donor wafer 3 against the host surface to hold its rear face against this host surface over its entire extent. This initial stress, which applies as long as the donor wafer 3 is at a relatively low temperature, close to room temperature, tends to be reduced as the temperature rises when the wafer is exposed to the ion beam. This extended intimate contact is therefore maintained, even when the temperature rises, without causing the thermal runaway that occurs in the prior art configuration.

FIG. 3D shows a variant of the second embodiment; In this variant, the elevation h of the support surface (taken at the base of the support, that is, relative to the main plane of the disk 1a) is at its highest at the wedge 2a. The convexity is therefore such that the donor wafer 3, when initially placed on the support 2, has one side in contact with the wedge 2a and a portion of its rear face close to this side in contact with the host surface. In this configuration, as the wheel rotates, the centrifugal force causes the donor wafer 3 to abut the wedge 2a and deform, in a controlled manner. More precisely, the forced contact of the side of the wafer 3 against the wedge 2a is obtained while the rear face close to this side is indeed in contact with the host surface of the support 2. The donor wafer 3 can be deformed to progressively develop the contact of its entire rear face with the host surface from the initial contact zone.

Using conventional clips, it can be tricky to hold the donor wafer 3 in the position shown in FIG. 3D when it is first placed on the support. Also, and advantageously, the support 2 can be fitted with at least one retractable pin 4, as shown in FIG. 3E. This pin 4 has a first end designed to come into contact with the rear face of the donor wafer 3 to help hold it in position. This first end can be shaped like a sphere to ensure point contact with the rear face and prevent damage. The pin cooperates with a spring 5 (or any other retaining mechanism) to be held in an elevated position wherein its first end has an elevation substantially corresponding to the elevation of the host surface at the wedge 2a. The stiffness of the spring 5 (or, more generally, of the holding mechanism) is chosen to be sufficiently low so as not to resist deformation of the donor wafer 3 when the implantation wheel is rotated. The deformation forces applied to the donor wafer tend to retract the pin so that it disappears when it becomes lodged in the support 2, thus bringing the rear face of the donor wafer 3 into intimate contact with the host surface of that support.

Depending on the nature of the materials making up the thick layer and the handling substrate constituting a donor heterostructure, the latter may deform differently under the effect of temperature. In a first configuration, when the coefficient of thermal expansion of the thick layer is higher than that of the handling substrate, this donor wafer tends to deform into a dome whose convexity (apex) is pointed away from the rear face. Conversely, in a second configuration, when the coefficient of thermal expansion of the thick film is lower than that of the handling substrate, the donor wafer tends to deform by orienting its convexity (its apex) toward the rear face.

In this embodiment, the convex shape of the wafer support 2 is naturally chosen so that it corresponds to the general shape of the wafer when it deforms under the effect of temperature, that is, the support has a concave recess or convex dome shape depending on the nature of the materials forming the donor wafer. Thus, the wafer support 2 shown in FIGS. 3B, 3D, and 3E is particularly suited to the first configuration of the donor wafer, and the wafer support shown in FIG. 3C is particularly suited to the second configuration.

The height of the apex of the convex shape naturally depends on the nature of the materials making up the donor wafer, its size and the temperature at which it can be received without triggering the exfoliation phenomenon during the implantation step. This height can be on the order of a millimeter, typically between 0.1 mm and 5 mm.

In this embodiment, it is not absolutely necessary to provide an elastomer layer, although it is generally very advantageous for this layer to be present. When present, this layer does not necessarily have a dimension such that it is in contact with the entire rear face of the donor wafer.

Of course, the two methods can be combined to provide a wafer support 2 with a convex shape and an elastomer layer in contact with the entire rear face of the donor wafer.

The convex shape of the support can be obtained by machining, particularly when the support is made of metal. When it comprises a superficial elastomer layer, this layer can have a variable thickness, thus defining the convex shape of the substrate.

More generally, the present disclosure is not limited to the embodiments described, and it is possible to add alternative embodiments without departing from the scope of the invention as defined by the claims.

1.-10. (canceled)

11. An ion implantation equipment, comprising:
an ion source; and
an implantation wheel, the equipment configured to form a plane of weakness in a plurality of donor wafers, the wheel comprising:
a main disk;
a plurality of wafer supports arranged on one face of the main disk, each wafer support having a host surface configured to receive a rear face of a donor wafer, each host surface of the plurality of wafer supports having a convex or concave shape, the convex or concave shape corresponding to a shape of a donor wafer when the donor wafer deforms under the effect of temperature; and
a cooling circuit for cooling the wafer supports and/or the main disk.

12. The ion implantation equipment of claim 11, wherein each host surface comprises a superficial elastomer layer on which the rear face of a donor wafer rests, the superficial elastomer layer having a dimension at least equal to that of the rear face of the donor wafer so as to enable the entire extent of the rear face of the donor wafer to be brought into contact with the wafer support.

13. The ion implantation equipment of claim 12, wherein the superficial elastomer layer has a variable thickness, this variable thickness defining the convex or concave shape of the wafer support.

14. The ion implantation equipment of claim 11, wherein the convex or concave shape is in the form of a concave recess or in the form of a convex dome.

15. The ion implantation equipment of claim 14, wherein the concave recess or convex dome has a height of between 0.1 mm and 5 mm.

16. The ion implantation equipment of claim 11, wherein the wheel has an axis of symmetry defining an axis of rotation and wherein each host surface of the plurality of wafer supports is oriented toward the axis of rotation so that a component of the centrifugal force normal to the host surface is applied to the donor wafer during rotation of the wheel and presses the donor wafer against the host surface.

17. The ion implantation equipment of claim 11, wherein each wafer support includes a wedge for retaining a donor wafer by opposing a component of the centrifugal force coplanar with the host surface applied to the donor wafer during rotation of the wheel.

18. The ion implantation equipment of claim 17, wherein the host surface of each wafer support has an elevation relative to the base of the wafer support that is highest at the wedge.

19. The ion implantation equipment of claim 18, wherein each wafer support includes a retractable pin.

20. The ion implantation equipment of claim 17, wherein each wafer support includes at least one clip configured to position and retain a wafer against the wedge.

21. The ion implantation equipment of claim 13, wherein the convex or concave shape is in the form of a concave recess.

22. The ion implantation equipment of claim 21, wherein the concave recess has a height of between 0.1 mm and 5 mm.

23. The ion implantation equipment of claim 22, wherein the wheel has an axis of symmetry defining an axis of rotation and wherein each host surface of the plurality of wafer supports is oriented toward the axis of rotation so that a component of the centrifugal force normal to the host surface is applied to the donor wafer during rotation of the wheel and presses the donor wafer against the host surface.

24. The ion implantation equipment of claim 13, wherein the convex or concave shape is in the form of a convex dome.

25. The ion implantation equipment of claim 24, wherein the convex dome has a height of between 0.1 mm and 5 mm.

26. The ion implantation equipment of claim 25, wherein the wheel has an axis of symmetry defining an axis of rotation and wherein each host surface of the plurality of wafer supports is oriented toward the axis of rotation so that a component of the centrifugal force normal to the host surface is applied to the donor wafer during rotation of the wheel and presses the donor wafer against the host surface.
